(19) United States
(12) Patent Application Publication
(10) Pub. No.: US 2015/0203966 A1
(43) Pub. Date: Jul. 23, 2015

(54) MEASUREMENT OF FILM THICKNESS ON AN ARBITRARY SUBSTRATE

(71) Applicant: Applied Materials, Inc., Santa Clara, CA (US)

(72) Inventors: Edward BUDIARTO, Fremont, CA (US); Thomas NOWAK, Cupertino, CA (US); Todd EGAN, Fremont, CA (US); Sergey STARIK, Kiev (UA)

(21) Appl. No.: 14/594,446

(22) Filed: Jan. 12, 2015

Related U.S. Application Data
(60) Provisional application No. 61/929,610, filed on Jan. 21, 2014.

(51) Int. Cl. C23C 16/52; G01B 11/06

(52) U.S. Cl. CPC C23C 16/52; G01B 11/0625

(57) ABSTRACT

Embodiments of the present disclosure enable measurement of film properties, such as thickness, using reflectometry regardless of the underlying pattern on the substrate or base layer because the amount of phase shift resulting from the growing film at any wavelength is independent of the substrate or base layer. One embodiment of the method includes determining properties of the substrate from a time series data. Another embodiment of the method includes removing a plasma background for measuring data by making two consecutive measurement with a light source on and off respectively. Another embodiment includes determining a deposition start time by monitoring a plasma marker or a phase shift of optical properties.

### CROSS-REFERENCE TO RELATED APPLICATIONS

This application claims priority to U.S. Provisional Patent Application Ser. No. 61/929,610, filed on Jan. 21, 2014, which herein is incorporated by reference.

### BACKGROUND

1. Field

Embodiments of the present disclosure relate to apparatus and methods for measuring thickness of films deposited on substrates with unknown surface properties.

2. Description of the Related Art

When measuring film thickness or other properties in conventional reflectometry, properties of the substrate underneath the film being measured are needed for calculating the properties of the film being measured. Thus, conventional reflectometry only functions properly when the substrate underneath is fully known. For example, when the substrate underneath is a bare silicon wafer, or a silicon wafer with a known stack of blanket films.

However, in semiconductor processing, processing chambers are usually used to depositing films on various substrates. Furthermore, films are usually deposited on substrates with a patterned surface. Even if the pattern is known, the point being measured may not fall in the same region of the pattern for each substrate being measured.

Therefore, there is a need for apparatus and methods for measuring properties of films formed on substrate locations with unknown surface properties.

### SUMMARY

Embodiments of the present disclosure relate to apparatus and methods for measuring thickness of films deposited on a random substrate location with unknown surface properties.

One embodiment of the present disclosure provides a method for measuring properties of a thin film. The method includes positioning a substrate having unknown surface properties in a processing chamber, repeatedly measuring a reflectance spectrum of the substrate at a time interval to obtain a time series data, flowing one or more processing gases to deposit the thin film over the substrate while maintaining repeated measurements, determining one or more properties the unknown surface of the substrate from a plurality of reflectance spectrum measurements in the time series data, and determining thickness of the thin film according to the one or more properties of the unknown surface and reflectance spectrum measurement of the thin film.

Another embodiment of the present disclosure provides a method for forming a film stack. The method includes positioning a substrate in a plasma processing chamber, repeatedly measuring a reflectance spectrum of the substrate at a time interval to obtain a time series data, igniting plasma of processing gases to alternately deposit a first film and a second film in over the substrate while maintaining repeated measurement of reflectance spectrum, determining a complex reflectivity of the substrate from a plurality of reflectance spectrum measurements in the time series data, and determining thickness of each first film or second film according to the complex reflectivity of the substrate and a reflectance spectrum measurement of each first film or second film.

Yet another embodiment of the present disclosure provides an apparatus for depositing one or more films. The apparatus includes a chamber body defining a processing volume, a substrate support disposed in the processing volume, and a metrology assembly disposed over the substrate support. The metrology assembly comprises a flash light source, a spectrometer, a plurality of optical fiber channels connected between the flash light source and the spectrometer. Each optical fiber is positioned to direct a light from the flash light source towards a measurement point on the substrate support, receive reflectance from the measurement point, and direct the received reflectance to the spectrometer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic sectional view of a plasma processing chamber according to one embodiment of the present disclosure.

FIG. 2 is a schematic sectional view of a film stack formed on a patterned substrate.

FIG. 3 is a flow chart of a method for measuring thickness of a plurality of films formed on a substrate having unknown surface properties.

FIG. 4 illustrates an example of time series data fitting for determining properties of a patterned substrate.

FIG. 5 illustrates an example of time series data fitting using time series data collected during depositing first three layers of a film stack.

FIG. 6 illustrates spectral fitting results at various stage of film stack deposition according to embodiment of the present disclosure.

FIG. 7 illustrates results of thickness measurement of a film stack according to one embodiment of the present disclosure.

FIG. 8 is a schematic flow chart showing a data buffering process according to one embodiment of the present disclosure.

FIG. 9 is a schematic block chart showing a parallel computing structure according to one embodiment of the present disclosure.

FIG. 10 includes a curve showing thickness of a polysilicon film reaching opacity as a function of wavelengths.

FIG. 11 schematically illustrates an example for a rolling substrate according to one embodiment of the present disclosure.

FIG. 12 illustrates normalization of a reflectance spectrum according to one embodiment of the present disclosure.

FIG. 13 includes linear fit of thickness results according to one embodiment of the present disclosure.

FIG. 14 illustrates plasma emission signature lines for determining time zero according to one embodiment of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

### Overview

Embodiments of the present disclosure relate to apparatus and methods for measuring thickness of films deposited on substrates with unknown surface properties. More particularly, embodiments of the present disclosure provide a non-destructive method for measuring thickness or other properties of a plurality of films formed over a substrate. One embodiment of the method includes determining properties of the substrate surface from a time series data. Another embodiment of the method includes removing a plasma background for measuring data by making two consecutive measurement with a light source on and off respectively. Another embodiment includes determining a deposition start time by monitoring a plasma marker or a phase shift of optical properties.

Embodiments of the present disclosure may be used to measure thickness or other properties of films being deposited on a substrate without knowing beforehand the surface properties of the substrate. Embodiments of the present disclosure measure thickness or other properties of the film in real time and may be used for closed loop control. Embodiments of the present disclosure may be used to measure thickness or other properties of a plurality of layers being formed. For example, embodiments of the present disclosure may be used in measuring thickness of vertical memory stacks, such as memory stacks of NAND flash memory which includes up to 72 layers of alternative films formed on top of a patterned under-layer on a substrate.

### Hardware

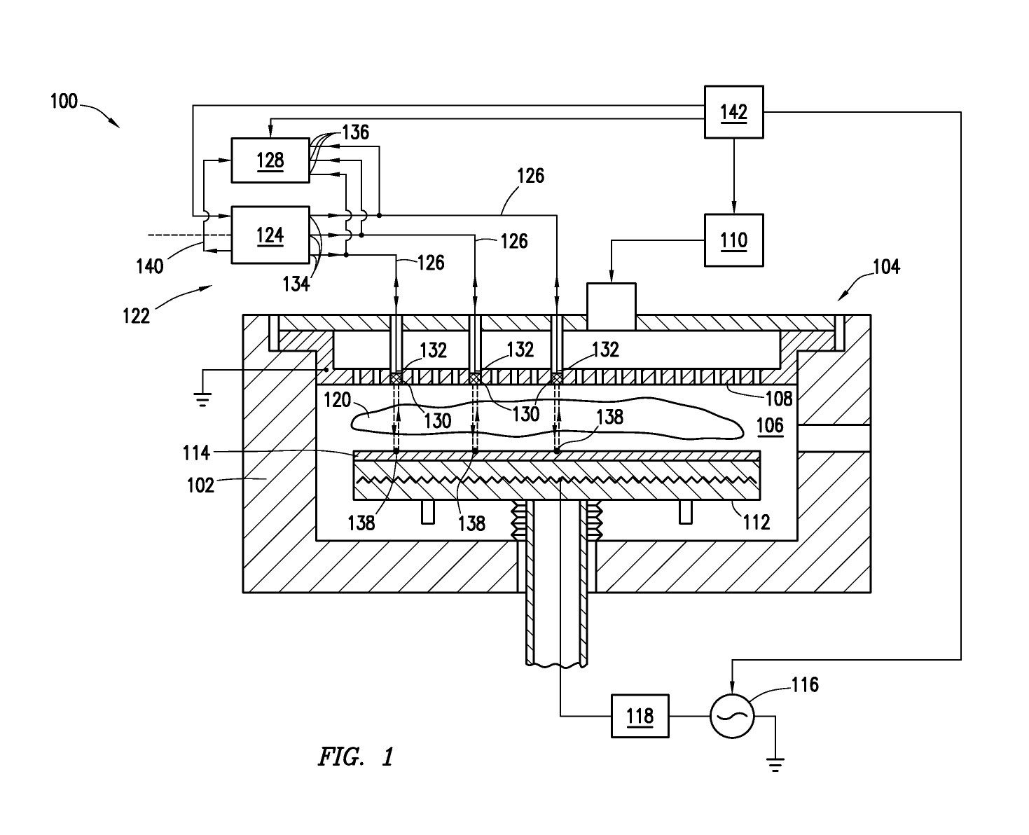

FIG. 1 is a schematic sectional view of a plasma processing chamber 100 according to one embodiment of the present disclosure. The plasma processing chamber 100 is capable of performing in-situ film property measurement without using information of a base layer on substrates being processed. For example, the plasma processing chamber 100 is capable of measuring thickness of films while forming film stacks for flash memory devices.

The plasma processing chamber 100 may include a chamber body 102 and a lid assembly 104 disposed over the chamber body 102. The chamber body 102 and the lid assembly 104 define a processing volume 106. The lid assembly 104 may include a shower head 108. A gas source 110 may be connected to the lid assembly 104 so that one or more processing gases from the gas source 110 may be delivered to the processing volume 106 through the shower head 108. A substrate support 112 may be disposed in the processing volume 106 for supporting a substrate 114 during processing. In one embodiment, a radio frequency (RF) power source 116 may be coupled to the substrate support 112 through a matching network 118. The RF power source 116 may apply a RF power between the substrate support 112 and the shower head 108 to generate plasma 120 for processing. In one embodiment, the plasma 120 may be used to deposition films by a chemical vapor deposition (CVD) process.

The plasma processing chamber 100 also includes an in-situ metrology assembly 122. The in-situ metrology assembly 122 may include a light source 124, one or more fiber-optic bundles 126 and a spectrometer 128. Each of the one or more fiber-optic bundles 126 has a first end 132 disposed outside a corresponding one observing window 130 in the shower head 108. Each fiber-optic bundle 126 has a second end 134 optically connected to the light source 124, and a third end 136 optically coupled to the spectrometer 128. Each fiber-optic bundle 126 is arranged to transmit light from the light source 124 towards the substrate 114 through the observing window 130 so that the light from the light source 124 travels towards a measuring point 138 on the substrate 114 at normal incident. The fiber-optic bundle 126 then captures reflection of the light from the substrate 114 from the normal incident and transmits the reflection towards the spectrometer 128. The fiber-optic bundle 126 may collimate the light from the light source 124 to illuminate about 2 mm in diameter at the measuring point 138.

The light source 124 may be a flash light source capable of dispersing pulsed light at short durations. The light source 124 may be a white light source. In one embodiment, the light source 124 may be a Xenon flash-lamp. The spectrometer 128 may include a charged-coupled device (CCD) array light detector. In one embodiment, the spectrometer 128 may measure unpolarized light with a wavelength range between about 200 nm to about 800 nm.

The observing windows 130 may be sapphire windows disposed in openings formed through the shower head 108. The one or more observing windows 130 may be positioned at various locations for corresponding to various radial locations of the substrate 114.

In one embodiment, a reference fibre-optic bundle 140 may be connected between the light source 124 and the spectrometer 128 to provide a reference channel to compensate any fluctuations/drifts overtime of the light source 124.

The plasma processing chamber 100 may include a system controller 142. The system controller 142 is connected to the in-situ metrology assembly 122. The system controller 142 may include a control software. When operating, the control software may instruct the in-situ metrology assembly 122 to perform measurement, receive and process measurement data from in-situ metrology assembly 122 to obtain properties of the substrate 114. The system controller 142 is also connected to the gas source 110, the RF power source 116 and other components of the plasma processing chamber 100 to perform process recipes.

Even though, three fiber-optic bundles 126 are shown for measuring three measuring points 138 on the substrate 114, more or less fiber-optic bundles 126 may be used according to process requirement. In one embodiment, two plasma processing chambers 100 may be positioned side by side and sharing the light source 124 and the spectrometer 128.

### Method Overview

Embodiments of the present disclosure include methods for in-situ measurement of properties, such as thickness, of multiple films formed on a random base layer on a substrate. The methods may be performed using the plasma processing chamber 100 described above. The methods may be used in measuring and controlling film thickness during formation of flash memory film stacks.

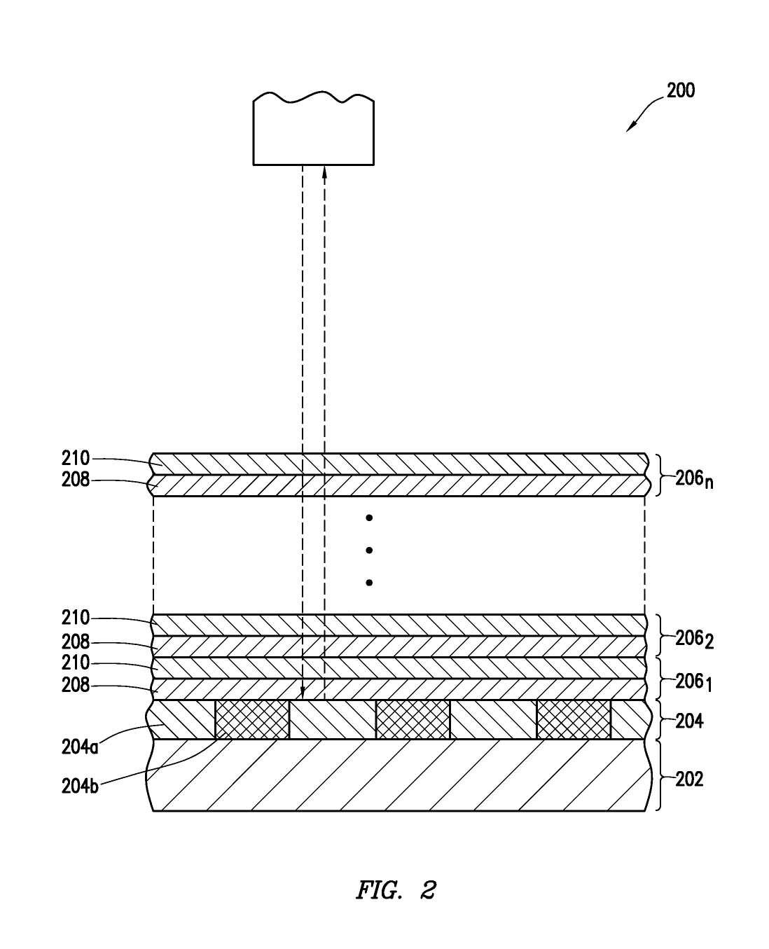

FIG. 2 is a schematic sectional view of a flash memory film stack 200. The film stack 200 may be formed a base layer 204 of a substrate 202. The base layer 204 may be a patterned layer including a first material 204a and a second material 204b. A plurality of film pairs 206₁-206ₙ are formed on the base layer 204 sequentially. Each film pair 206 may include a first film 208 and a second film 210 so that the film stack 200 includes a plurality of first films 208 and second films 210 formed in alternation. The plurality of film pairs 206₁-206ₙ may be formed by chemical vapor deposition in one processing chamber, such as the plasma processing chamber 100.

In one embodiment, the flash memory film stack 200 may be a NAND architecture having up to 72 layers of Nitride-Oxide (NO) or Oxide-Polysilicon (OP) films. Each film 208, 210 may be about 200 A to 500 A thick. The number and thickness of the layers in the film stack 200 preclude post-processing measurement using non-destructive optical tools such as ellipsometers or reflectometers. Furthermore, the ellipsometers or reflectometers can measure the total thickness of the film stack 200, but not able to resolve the individual film thickness at once, after all films are deposited. Traditionally, thickness of individual film can only be measured by destructive measurement techniques, such cross-section transmission electron microscopy (TEM).

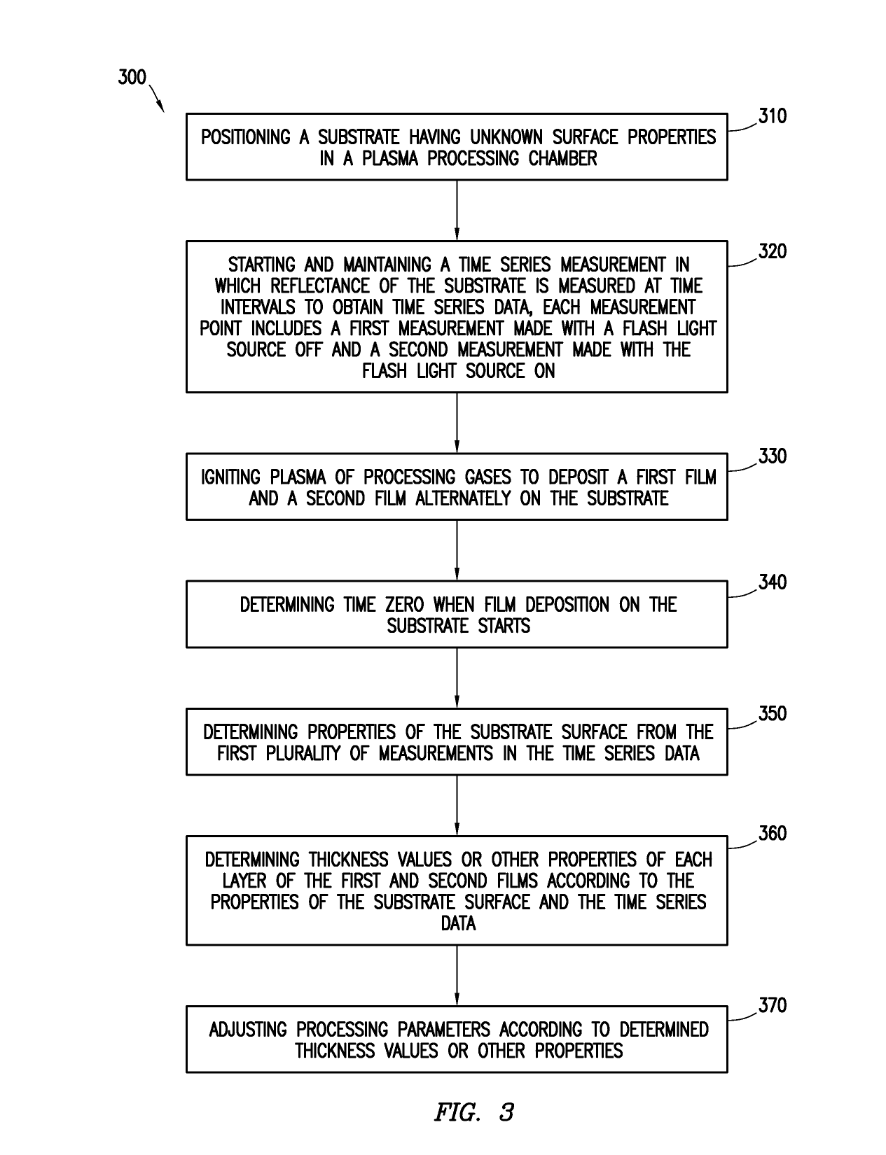

Embodiments of the present disclosure provide apparatus and methods for measuring thickness of individual films 208, 210 in-situ. FIG. 3 is a flow chart of a method 300 for measuring thickness of a plurality of films formed on a substrate having unknown surface properties according to one embodiment. Particularly, the method 300 may be used to measure thickness of individual films in a flash memory film stack, such as the film stack 200, without pre-knowledge of a base layer on which the film stack is formed while forming the film stack in a deposition chamber. The method 300 may be performed using a plasma processing chamber having a metrology assembly, such as the plasma processing chamber 100.

In block 310, a substrate being processed is positioned in a processing chamber. Surface properties of the substrate may be unknown or patterned.

In block 320, measuring optical properties, such as reflectance, of the substrate repeatedly. The measurement may be collected by and stored in a controller as a time series data for analysis. The repeated measurement is maintained in the duration of deposition of the films to be measured. In one embodiment, one measurement point may be made in every equal and continuous time intervals. Length of the time interval may be a predetermined according to processing recipes so that enough time series data may be collected to determine properties of the base layer and the layers to be formed. The measurement may be made using a metrology assembly, such as the metrology assembly 122, by impinging light from a light source to the surface of the substrate at normal incident and detecting reflections of the impinging light.

In one embodiment, each measurement point may include two measurements made immediately next to one another time wise. The first measurement may be made by measuring reflections from the substrate surface without turning on the light source. The second measurement may be made by measuring the reflection with the light source turning on. By comparing the first and second measurements, noise from background, such as plasma and emissions of the substrate and other chamber components may be removed.

In one embodiment, collected data in each measurement point may include intensities of reflections at a plurality of wavelengths within a measurement spectrum. In one embodiment, the measurement spectrum may be chosen according to properties and thickness of the films being measured. In one embodiment, the measurement spectrum is between about 200 nm in wavelength and about 800 nm in wavelength.

In box 330, igniting and maintaining plasma of one or more processing gases in the processing chamber to facilitate a deposition process on the substrate surface. When more than one film may be formed in the process recipe, processing gases may be switched and/or changed during processing. In one embodiment, two combinations of processing gases may be switched alternatively to deposit two different kinds of films in alternation. As described in box 320, repeated measurements separated by time intervals are continuously performed during igniting and maintain the plasma for film deposition.

In box 340 to box 360, the time series data collected from the repeated measurements is analyzed in order to obtain properties of the films deposited on the substrate. In box 340, time zero indicating the starting time of deposition may be determined. In one embodiment, time zero may be obtained by acquiring the time at which the plasma for deposition is ignited. Alternatively, time zero may be determined by detecting a plasma marker or a phase shift in the time series data. Details for detecting the plasma markers and phase shift are discussed in later section. Data in the time series data collected after time zero will be used in determining properties of the substrate/base layer and the films being deposited.

In box 350, properties of the base layer, such as reflectivity of the base layer, may be determined from a first plurality of measurements in the time series data obtained after time zero. In one embodiment, properties of the base layer may be determined by numerically solving recursive equations representing a mathematical model of film stacks. Embodiments for determining base layer properties are discussed in later sections.

In box 360, properties, such as thickness, of each film layer being deposited in the processing chamber may be determined according to the properties of the base layer and the time series data. In one embodiment, properties of the layers being deposited may be determined by numerically solving recursive equations representing a mathematical model of the film stacks. Details for determining the film properties are discussed in later sections. Using currently available computational resources, properties of each film being processed can be determined in real time once the delay for determining the properties of the base layer is overcome.

In box 370, when properties of the film being processed are determined at real time, the determined properties may be used to adjust processing parameters to obtain desired process result. For example, in depositing film stacks for flash memory, it is desirable to have uniform thickness among the plurality of film layers of the same composition. Processing parameters can be adjusted when a film being formed is deviating from a desired thickness.

### Removing Plasma Background

As discussed in box 340 of the method 300, measurement points obtained by spectrometer may include noises from environment. For example, a typical plasma enhanced CVD process creates plasma inside the processing chamber to aid the deposition process, the plasma emits lights at various wavelengths which are received by the fiber bundle of the spectrometry along with reflections of the impinging light from the light source. This plasma emission is an unwanted interference in the measurement data. Embodiments of the present disclosure include removing by using a flash or pulsed light source and taking two measurements to remove noises from continuous source, such as plasma emission, from the measurement data. In one embodiment, plasma interference or other noise from continuous sources, are removed from measurement data by collecting two measurements in each data point in time, a first measurement with the light source on and a second measurement with the light source off, and subtracting the second measurement from the first measurement. The first and second measurements are taken within close proximity in time within one time interval so that the noises, such that the plasma interference, in the two measurements are substantially similar. The measurement with the light source on can be taken before the measurement with the light source off, or vice versa.

Obtaining Substrate Properties from Time-Series Data

Thickness and other properties of a thin film may be determined from measurement of a reflectance of the thin film using a film stack model if properties of a substrate or a base layer underneath the thin film are known. However, in semiconductor processing, properties of the substrate or the base layer at the measurement points may not be known prior to a process being performed for various reasons, such as the base layer is patterned, changes to the base layer prior to the process, changes to process, or simply unknown. Embodiments of the present disclosure provides a method for determining properties of the substrate or base layer from time series data obtained during formation of one or more layers formed on the substrate or base layer.

According to one embodiment of the present disclosure, reflectivity of the substrate or the base layer can be obtained by numerically solving a mathematical model representing a multi-layer film stack in form of the following equations:

$$\begin{matrix}f ( λ , t ) = w {\vert {F}_{j}^{s} ( λ , t ) \vert}^{2} + ( 1 - w ) {\vert {F}_{j}^{p} ( λ , t ) \vert}^{2} & Equation 1 \\ {F}_{j}^{s} ( λ , t ) = \frac{{r}_{j} ( 1 - {r}_{j} {F}_{j - 1}^{s} ) + ( {F}_{j - 1}^{s} - {r}_{j} ) {e}^{- {i2β}_{j}}}{1 - {r}_{j} {F}_{j - 1}^{s} + {r}_{j} ( {F}_{j - 1}^{s} - {r}_{j} ) {e}^{- {i2β}_{j}}} & Equation 2 \\ {F}_{j}^{p} ( λ , t ) = \frac{{r}_{j} ( 1 - {r}_{j} {F}_{j - 1}^{p} ) + ( {F}_{j - 1}^{p} - {r}_{j} ) {e}^{- {i2β}_{j}}}{1 - {r}_{j} {F}_{j - 1}^{p} + {r}_{j} ( {F}_{j - 1}^{p} - {r}_{j} ) {e}^{- {i2β}_{j}}} & Equation 3 \\ {β}_{j} ( λ , t ) = \frac{2 π ( {n}_{j} - {ik}_{j} ) {D}_{R , j} t}{λ} & Equation 4 \\ {r}_{j} = \frac{( 1 - {n}_{j} ) + {ik}_{j}}{( 1 - {n}_{j} ) - {ik}_{j}} & Equation 5 \\ {F}_{0}^{s} ( λ ) = {A}_{sub}^{s} ( λ ) {e}^{{iφ}_{sub}^{s} ( λ )} & Equation 6 \\ {F}_{0}^{p} ( λ ) = {A}_{sub}^{p} ( λ ) {e}^{{iφ}_{sub}^{p} ( λ )} & Equation 7\end{matrix}$$

Equation 1 expresses unpolarized reflectance f(λ,t) of a film stack in terms of s-polarized reflectivity Fⱼs(λ,t) and p-polarized reflectivity Fⱼ^{p}(λ,t) of the film stack. Here A denotes wavelength and t denotes time which starts at the beginning of film deposition. The superscripts s and p refer to the s and p polarization of the light source when it is reflected from a patterned substrate. The weight parameter w represents the fraction of the light that is s-polarized. If the substrate is a bare silicon wafer or the base layer is an isotropic blanket film, and the light is incident normally to the wafer, the s and p components become identical and w equals 0.5.

Equations 2 and 3 are recursive form of the Fresnel equations expressing that the complex reflectivity Fⱼ^{s}(λ,t), Fⱼ^{p}(λ,t) at the j^{th} layer in a film-stack, which includes j layers of films with the j^{th} layer is the top-most layer, as a function of the reflectivity Fⱼ₋₁^{s}(λ,t), Fⱼ₋₁^{p}(λ,t) of the film-stack at the (j−1)^{th} layer. nⱼ and kⱼ are real and imaginary refractive indices of the j^{th} film. nⱼ and kⱼ are known constant when composition of the film is known. D_{R,j} represents deposition rate of the j^{th} film. Thickness of the j^{th} film at time t can be obtained from deposition rate D_{R,j} and the time the j^{th} film being deposited.

When the first layer is the top most layer, when j=1, the complex reflectivity F₁^{s}(λ,t), F₁^{p}(λ,t) is a function of reflectivity of the substrate or the base layer F₀^{s}(λ), F₀^{p}(λ). Equations 6 and 7 are complex reflectivities of the substrate or base layer in terms of amplitude and phase.

When the reflectivity of the substrate or base layer is unknown, the film-stack model of equations 1-7 includes 5 parameters to be calculated. The 5 parameters are: deposition rate D_{R,j}, amplitude values A_{sub}^{s}(λ), A_{sub}^{p}(λ) of the complex reflectivity of the substrate/base layer, and phase values φ_{sub}^{s}(λ), φ_{sub}^{p}(λ) of the complex reflectivity of the substrate/base layer. When a measurement point is made at time t using a metrology assembly, such as the metrology assembly 122 discussed above, one unpolarized reflectance f(λ,t) is collected at any wavelength λ. Having only one measurement point and five unknown parameters, the film-stack model of equations 1-7 cannot be solved using conventional (static) algorithms for spectrometry.

According one embodiment of the present disclosure, a time series data may be collected by making a plurality of measurement points at time intervals during deposition of the first film. The time series data provides additional data points needed to determine all 5 parameters in the film-stack model of equations 1-7. The time series data may be collected at time intervals that allow enough phase shift/variation between individual measurements in the time series data. In one embodiment, the time series data may be collected by measuring reflectance of the substrate at equal time intervals, for example about 100 ms, during deposition of the first film.

In one embodiment, the complex reflectivity of the substrate/base layer and the deposition rate (or thickness) of the film may be determined by fitting the time-series data dynamically with the film-stack model. Determining the properties of the substrate/base layer as described in box 350 of the method 300 may be performed by fitting the time-series data collected during deposition of the first film layer.

During fitting the time-series data, estimated values of the complex reflectivity of the substrate/base layer and deposition rate are plugged into the film-stack model, such as equations 1-7, to compute an estimated reflectance for each time point when a measurement is made to yield an estimated time-series of reflectance. The estimated time-series of reflectance is compared to the actual measurement in the time-series data to yield a difference. The estimated values of complex reflectivity of the substrate/base layer and deposition rate are adjusted according to the difference and then plugged into the film-stack model to compute another estimated time-series of reflectance for another comparison to the measured time-series data. The adjusting, computing and comparing may be performed repeatedly until the yield difference between the estimated time-series of reference and the measured time-series data is within a threshold value, thus, the time-series data is fitted by the estimated values of complex reflectivity of the substrate/base layer and the deposition rate. Suitable numeral approaches may be used to compute the difference and adjust estimated values.

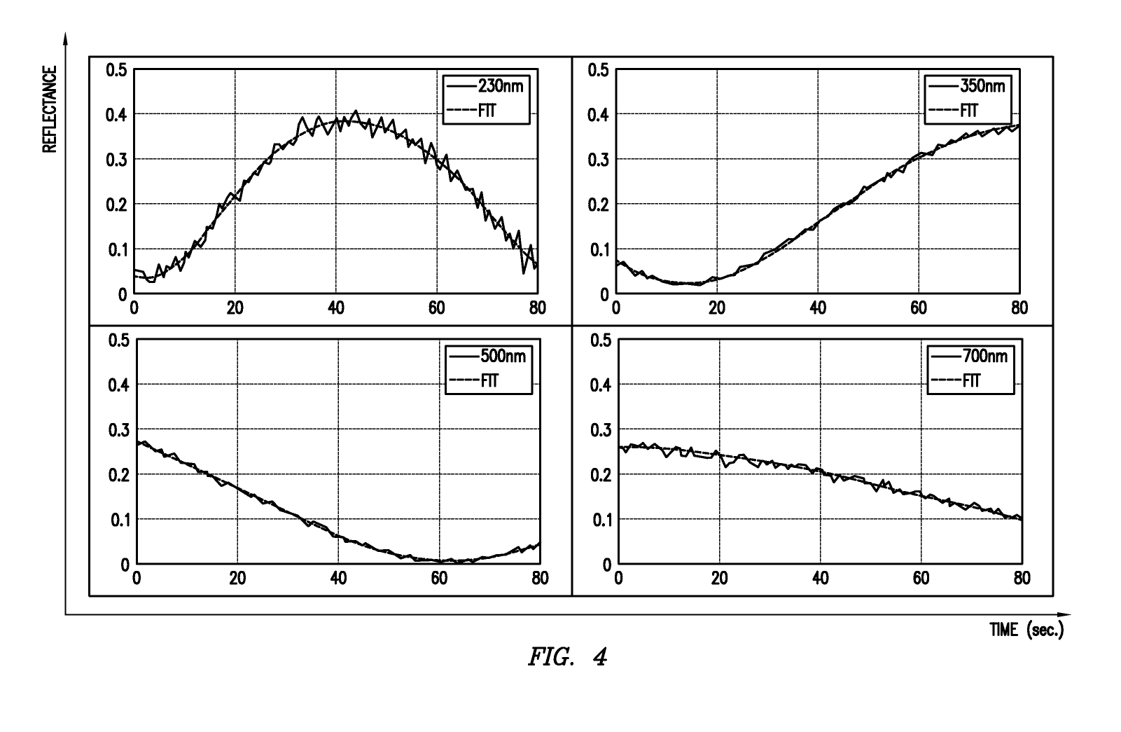

According to embodiments of the present disclosure, the fitting of time series data may be performed in parallel at a plurality of wavelengths. FIG. 4 illustrates an example of time series data fitting at wavelengths 230 nm, 350 nm, 500 nm and 700 nm respectively. The time series data in FIG. 4 are collected during depositing 500 Angstrom of a silicon nitride layer on a patterned substrate. As shown in FIG. 4, reflectance of a film stack varies with thickness. Patterns of the reflectance-thickness variation also depend on wavelength. Typically, the variation of reflectance with thickness has a higher frequency at a shorter wavelength than at a longer wavelength. By fitting the time series at a plurality of wavelengths, embodiments of the present disclosure employ the variation of different wavelengths to obtain accurate results.

To further improve accuracy in time-series data fitting, time-series data measurement may be taken during deposition of the first two or more layers. Particularly, when the first deposited layer is not very thick, the phase-shift information in the time-series data may not be sufficient to produce accurate substrate/base layer reflectivity. Any inaccuracy in the reflectivity of the substrate/base layer may cause larger errors in the thickness of the subsequent layers determined from the static stack-film model. In one embodiment, reflectivity of the substrate/base layer may be determined by fitting a time series data collected during deposition of the first two or more layers to improve accuracy in the determined reflectivity of the substrate/base layer.

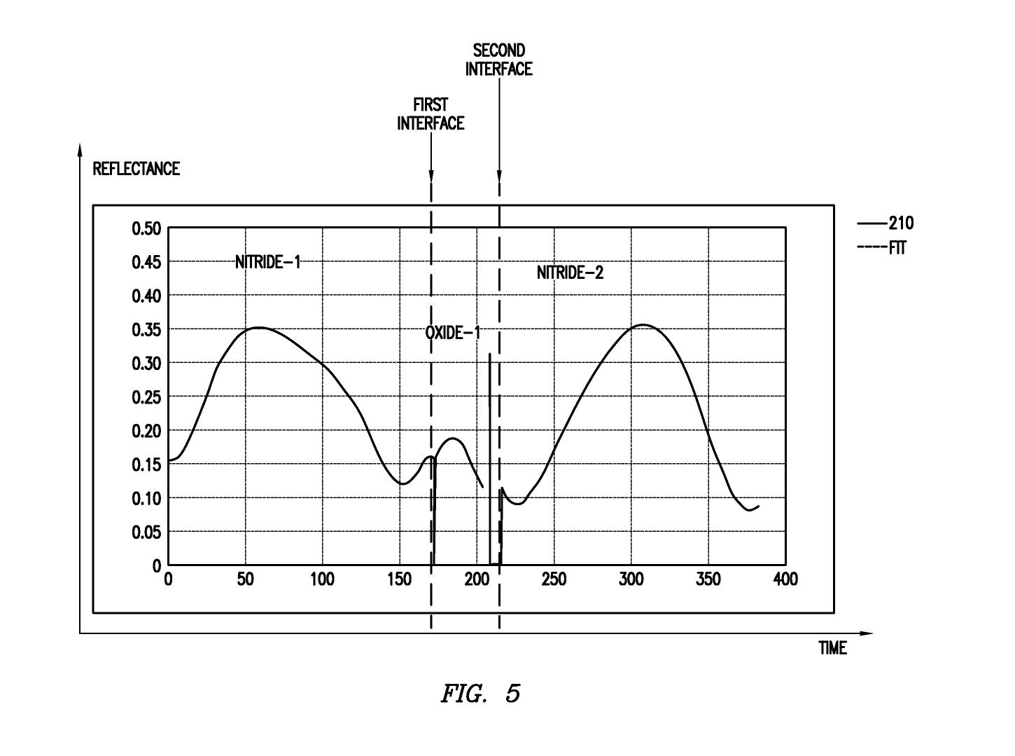

FIG. 5 illustrates an example of time series data fitting using time series data collected during depositing first three layers of a film stack. The first three layers are 500 A of silicon nitride, 300 A of silicon oxide, and 500 A of silicon nitride. As shown in FIG. 5, three layers of film provide additional variation in measured reflectance to improve accuracy of the determined reflectivity of the substrate/base layer.

Once the reflectivity or the substrate/base layer is computed, the static mode of the film-stack model can be used to solve for the thickness of subsequent layers as the subsequent layers are deposited. In one embodiment, the unknown thickness at any given time t can be solved in the film-stack model by performing a least square fit, or other numerical approximations, to the measured reflectance as a function of wavelength. Box 360 of the method 300 may be performed by fitting the measured spectra using the static mode of the film-stack model.

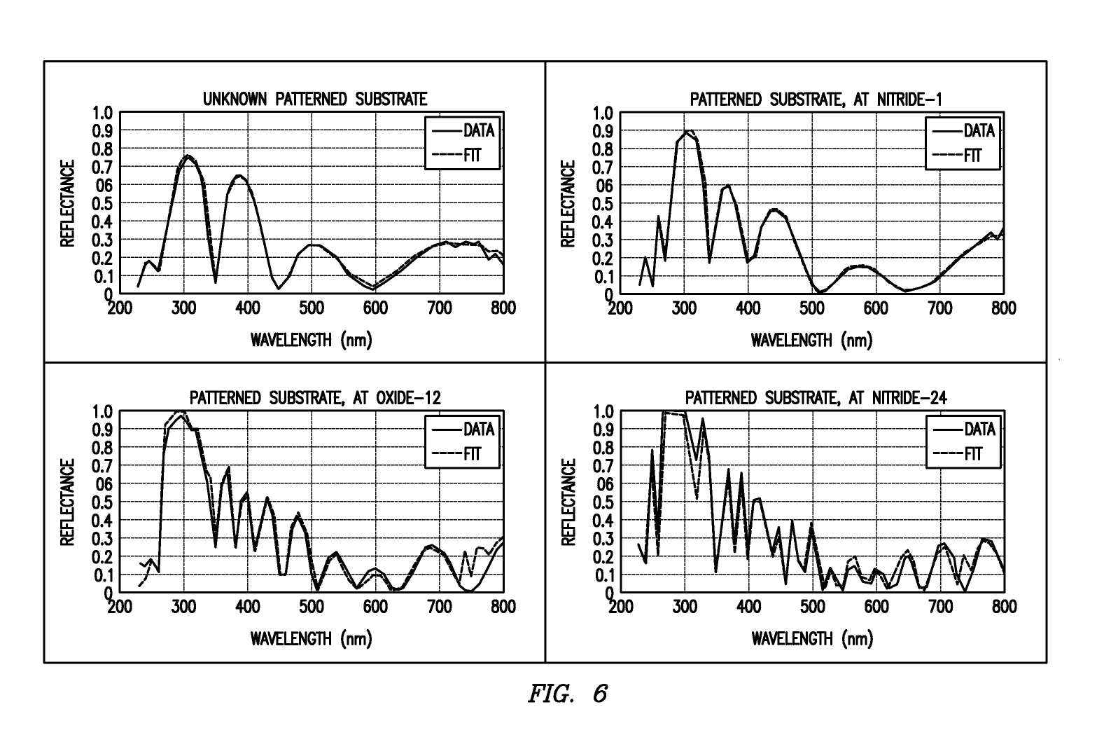

FIG. 6 illustrates spectral fitting results at various stages of film stack deposition according to embodiment of the present disclosure. The top-left plot in FIG. 6 shows the reflectance spectrum of an unknown patterned substrate that has been successfully calculated by fitting the time-series data from the first layer, a 500 A thick silicon nitride layer. The determined substrate's complex reflectivity enables accurate fitting of all reflectance spectra in the deposition of 24 nitride-oxide pairs on top of that patterned substrate. The remaining three plots in FIG. 6 show examples of such spectral fitting at the end deposition of the first silicon nitride layer, the 12^{th} silicon oxide layer, and the 24th silicon nitride layers respectively.

The result of the spectral fitting at the end deposition of each layer, such as the spectral fitting illustrated in FIG. 6, provides the thickness of the corresponding layer. FIG. 7 illustrates results of thickness measurement of a film stack according to one embodiment of the present disclosure. FIG. 7 includes thickness measurement results of a film stack having alternating silicon nitride and silicon oxide layers formed on a patterned substrate. The target thicknesses for the silicon nitride and the silicon oxide films are 500 A and 300 A respectively, except for every 6th pair of films, where the target thicknesses are 350 A and 200 A respectively. In FIG. 7, the thickness result of the present disclosure is compared to transmission electron microscopy (TEM) cross-section measurements. FIG. 7 illustrates that thickness measurement results according embodiment of the present disclosure are within the expected uncertainties of the TEM.

### Data Buffering

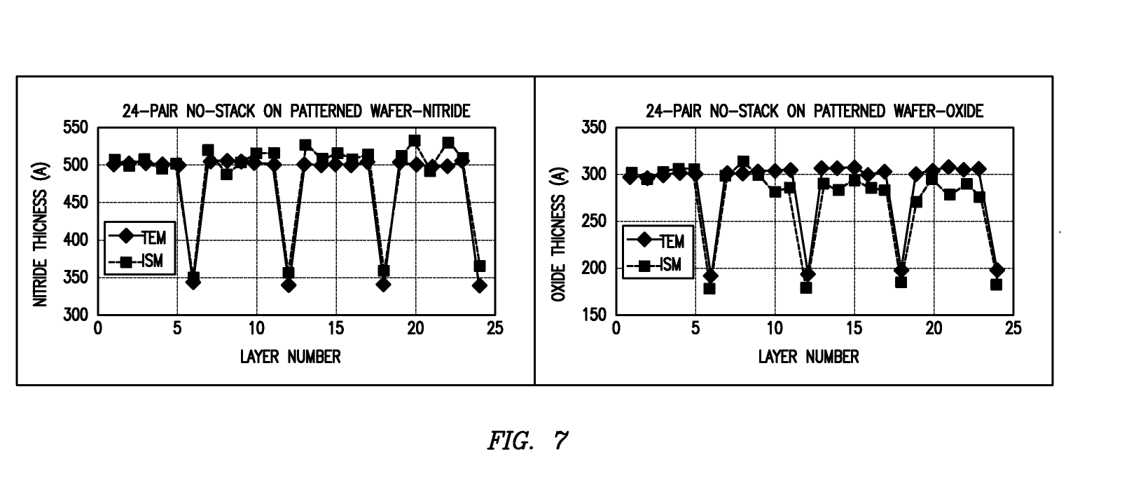

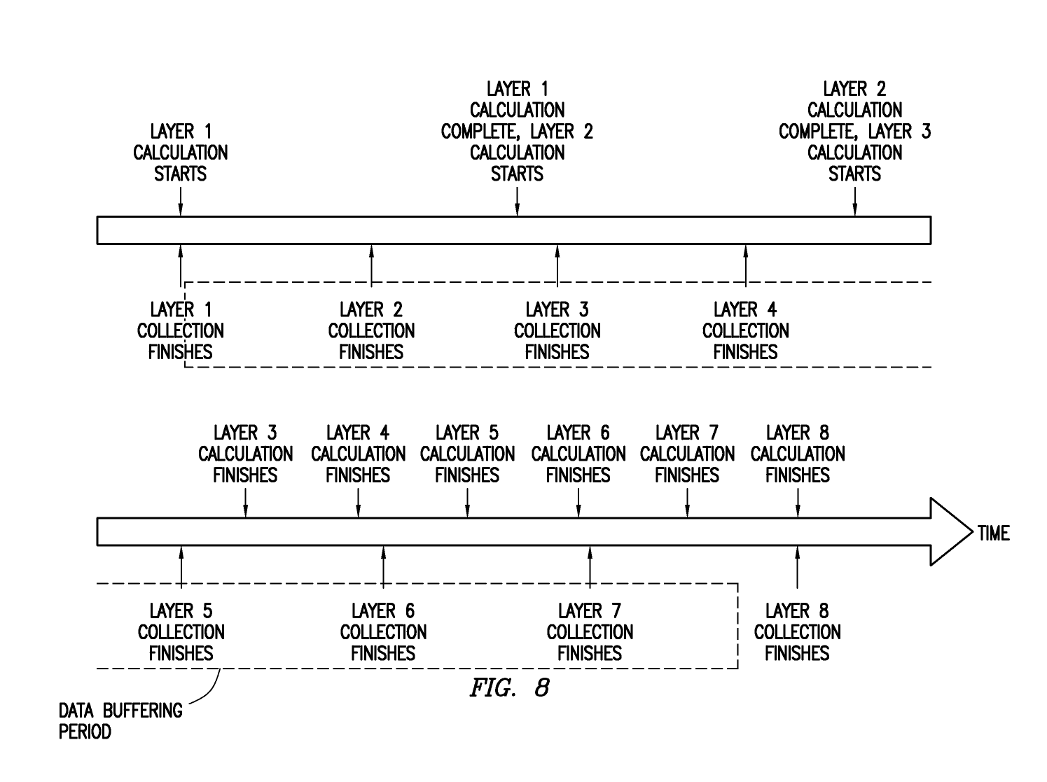

As discussed above, embodiments of the present disclosure may be used to measure thickness or other properties of films in a film-stack during deposition of the film stack. Theoretically, real time thickness of each film can be calculated using embodiments of the present invention. However, in cases when computational resource cannot satisfy the intensive computation involved, especially during the initial dynamic time-series fit to solve for the unknown substrate reflectivity, the calculation may lag behind the continuous stream of incoming data from the metrology assembly as the films are deposited. One embodiment of the present disclosure includes providing a data buffer within the system controller, such as in data storage of a computer, to store the measurement data from the metrology assembly while the computer processor is performing the time-series fitting to calculate the substrate reflectivity. After the substrate reflectivity calculation is completed, a faster algorithm, such as algorithm for static fitting, may be used to process the buffered data to calculate thickness of the deposited films, and eventually catch up with the real-time data stream. FIG. 8 is a schematic flow chart showing a data buffering process according to one embodiment of the present disclosure. FIG. 8 illustrates calculations and data collections along the time axis. Collected data are stored in a buffer during a data buffering period until the calculation catches up with the data collection.

### Parallel Computing

In one embodiment of the present disclosure, multiple computer processors (cores) and/or multiple graphical processing units (GPU), or Field Programmable Gate Arrays (FPGA), may be used to perform the dynamic fit calculation in parallel to keep up with the real-time data stream or to reduce the delay between data calculation and data collection occurred to the first multiple layers. In one embodiment, parallel computing may at least reduce the computation time to less than half the time it takes to deposit the first layer of film. Parallelization of the computation across multiple processors can be accomplished by dividing the data into two or more groups of wavelengths or two or more groups of time, and assigned each group to a different processor.

In one embodiment, multi-cores/GPUs/FPGAs are used in parallel for processing data from multiple data collecting channels. For example, in the plasma processing chamber 100 of FIG. 1, multiple measurement points 138 on the substrate 114 may be made at each time point. Data collected from each of the multiple measurement points 138 may be processed in parallel by one or more of the multi-cores/GPUs/FPGAs in the system. Similarly, multi-cores/GPUs/FPGAs may be used when multiple substrates are processed simultaneously, for example two substrates can be processed simultaneously in a twin chamber configuration, each substrate may be measured through one or more channels.

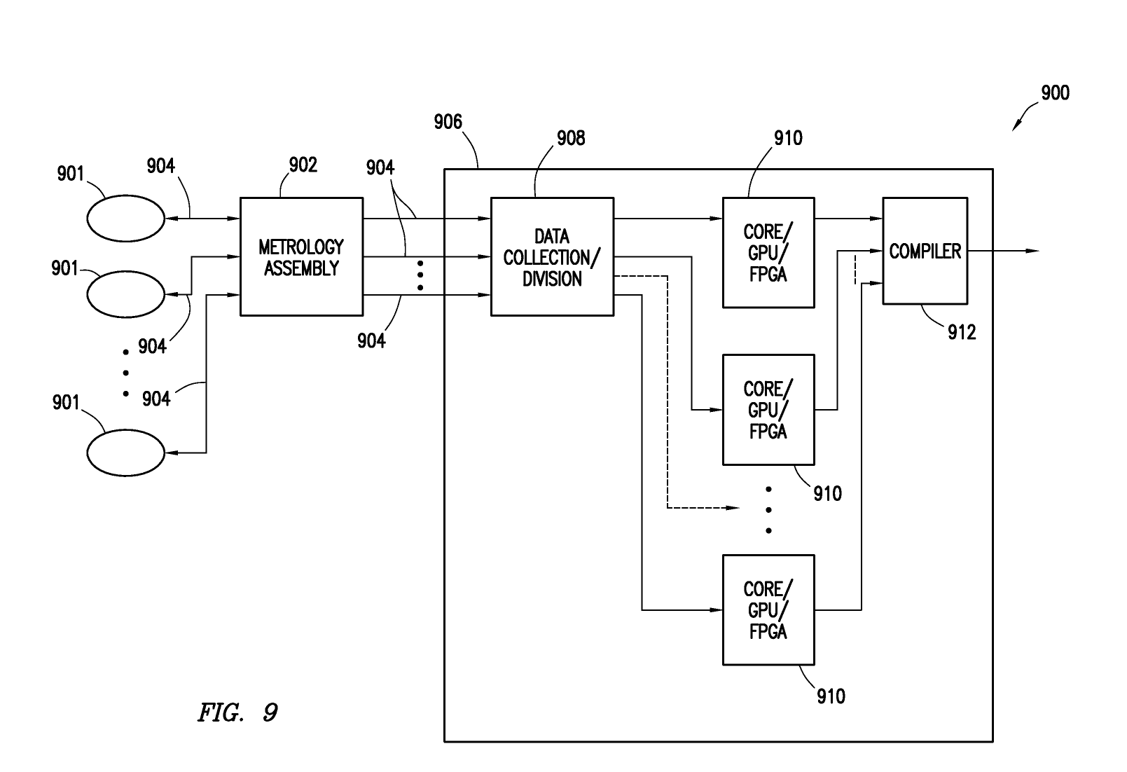

FIG. 9 is a schematic block chart 900 showing a parallel computing structure according to one embodiment of the present disclosure. One or more substrates 901 may be processed, such as having a film stack deposited, simultaneously. A metrology assembly 902 may be used to collect data from the one or more substrates 901. Data may be collected through a plurality of channels 904. The metrology assembly 902 may be connected to a data processing unit 906. The data processing unit 906 includes a data collection and division unit 908. The data collection and division unit 908 receives measurement data from the plurality of channels 904 of the metrology assembly 902 and divides the collected data by to a plurality of groups, each group of data is sent to one of a plurality of computing units 910 for parallel processing. The data collection and division unit 908 may group the data by wavelengths, by channels, and/or by time. Each computing unit 910 may include a computer processor (cores) and/or multiple graphical processing units (GPU), or Field Programmable Gate Arrays (FPGA). The plurality of computing units 910 process the data in parallel. In one embodiment, the data processing unit 906 may include a compiler 912 to compile calculation results from the plurality of computing units 910 to obtain a final result.

### Measuring Transparent Films

Embodiments of the present disclosure further include modifying calculation algorithms according to properties of the film being deposition. In one embodiment, multiple variations of the computing method described above may be used for measuring multiple types of films or film combinations. For example, different variations of computing methods may be used to measure silicon nitride, silicon oxide, and poly-silicon films. For transparent films, such as a stack of silicon nitride-silicon oxide pairs (silicon nitride is mostly transparent in the wavelength range of 230 nm to 800 nm), the most accurate result can be obtained by performing the time-series fit across one layer or multiple layers of data for calculating the unknown substrate reflectivity, followed by static fitting for the rest of the layers. However, when less accuracy can be tolerated, or faster computation time is desired, the time-series fit can be performed over fewer wavelengths. In one embodiment, when certain limitations from the hardware cannot be avoided, such as the spectrometer's finite wavelength resolution, some of the shortest wavelengths, for example wavelengths shorter than about 300 nm, can be excluded from the calculation since wavelengths shorter than about 300 mn are most affected by the wavelength resolution limit of the hardware.

### Measuring High Index or Highly Absorbing Films

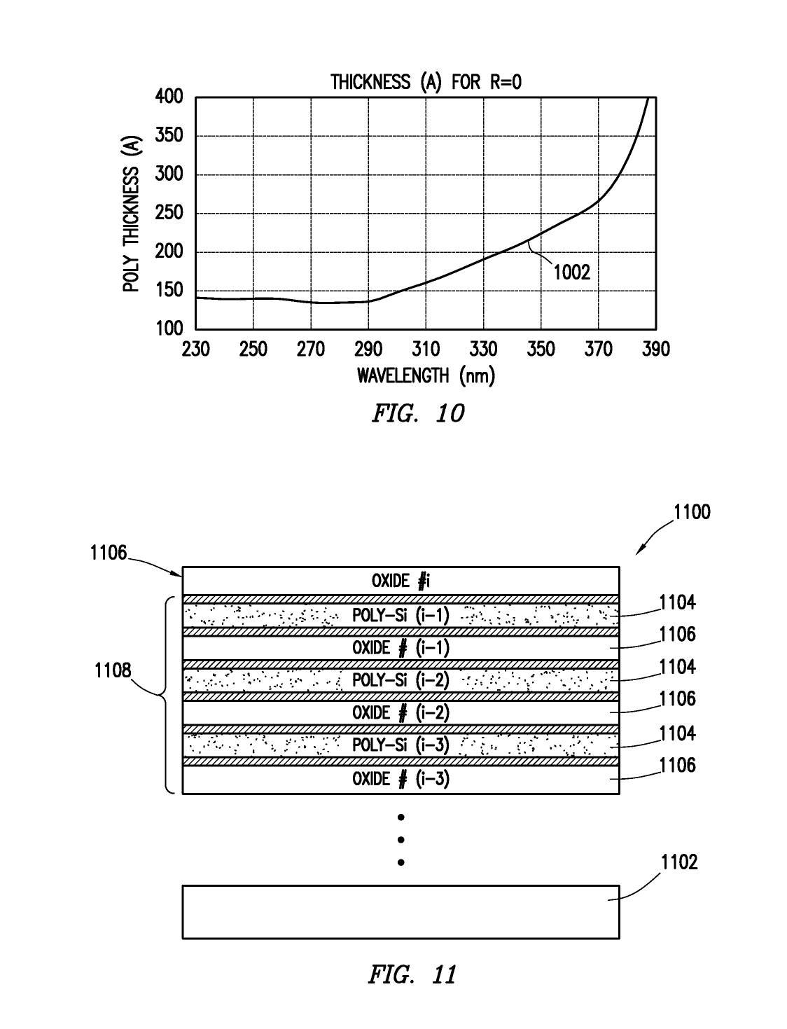

In one embodiment, thickness of a high index film may be extracted by direct fringe (cycle) counting of reflectance vs. time data. The large real refractive index (n) in high index films, such as amorphous silicon or polysilicon, allows direct fringe (cycle) counting of the reflectance vs. time data to extract the thickness of the film. In one embodiment, fringe counting method may be performed at shorter wavelengths where the index is higher. In an alternative embodiment, thickness of highly absorbing films, such as amorphous silicon or polysilicon, may be calculated based on the onset of opacity of the film as a function of wavelengths since the films are absorbing especially at the short wavelengths. FIG. 10 includes a curve 1002 showing thickness of a polysilicon film reaching opacity as a function of wavelengths.

### Measuring Transparent-High Absorbing Film Pairs

For a combination of transparent and highly absorbing films, such as a stack of silicon oxide-polysilicon (OP) pairs, a rolling substrate method may be used to measure thickness of layers in the film stack. For the first few pairs, such as first three pairs, of transparent and highly absorbing films, the dynamic-to-static fit method used for transparent film pairs, such as silicon nitride-silicon oxide pairs, may be utilized. After the several pairs, for example, 3 pairs, of the transparent-high absorbing films have been formed on the substrate, the substrate may become invisible to a spectrum beginning at a cut-off wavelength due to the high absorption of the high absorbing film. When the substrate becomes invisible to wavelengths shorter than about 600 nm, the cut-off wavelength is about 600 nm. The exact cut-off wavelength depends on the specific properties, including thickness, of the high absorbing film. When the original substrate becomes invisible, properties of the original substrate can be ignored in the film-model and replaced by the stack of the few most recent pairs of transparent-high absorbing films. The thicknesses of the few most recent pairs of transparent-high absorbing films are continuously updated as more films are deposited, creating effectively a “rolling” substrate.

FIG. 11 schematically illustrates an example for a rolling substrate according to one embodiment of the present disclosure. In FIG. 11, a film stack 1100 is formed on an original substrate 1102. The film stack 1100 includes a plurality of pairs of a high absorbing film 1104 and a transparent film 1106. When the film stack 1100 reaches certain thickness, the original substrate 1102 is no longer visible through the layer being deposited because of the high absorbing films 1104. According to one embodiment of the present disclosure, the top most film may be measured as if it were formed directly on a rolling substrate 1108. In one embodiment, the rolling substrate 1108 may include two or more pairs of the high absorbing films 1104 and the transparent films 1106 immediately beneath the top most layer. Properties of the rolling substrate 1108 may be determined from properties of the two or more films pairs of the rolling substrate 1108. During processing, properties of the rolling substrate 1108 may be updated for each layer of film 1104, 1106 or for each pair of films.

### Measuring Substrate Sensitivity Function

The reflectance spectrum of a film-stack depends on the substrate on which the film-stack is being formed, especially for transparent films such as silicon nitride-silicon oxide pairs. The measurement sensitivity to thickness is directly proportional to how much this reflectance spectrum changes with an incremental change in the top film thickness. As a result, the same film-stack can have different measurement sensitivities when formed on different substrates. When the substrate is unknown, measurement sensitivity of the film-stack is also unknown.

One embodiment of the present disclosure includes determining measurement sensitivity of a film-stack by computing sensitivity function of the substrate on which the film-stack is formed. Sensitivity function is the derivative of reflectance with respect to thickness. Sensitivity function is wavelength dependent. In one embodiment, spectral sensitivity function may be calculated to identify wavelength regions with the highest measurement sensitivity to thickness. Subsequent computations may be tuned to the identified wavelength regions for maximized accuracy and/or computational speed. After the wavelength regions with the highest measurement sensitivity have been identified for one substrate, subsequent substrate of the same kind may use the same identified wavelength regions without undergoing sensitivity computation.

### Minimizing Noises

As with any measurements, reflectance spectrum measured by metrology assemblies may include various noises that could negatively affect the accuracy. Embodiments of the present disclosure also includes various methods for minimize the effects of noise in the reflectance spectrum.

In one embodiment, a moving average may be applied to the reflectance spectrum. The moving average may be calculated across time over a predefined window, for example over a number of time intervals, and with a predefined weight for the original reflectance spectrum in each time interval. For example, the window size is five time intervals and weight for measurement in each time interval is 0.2. In another example, the window size is five time intervals and weight for measurement in each time interval is 0.33, 0.267, 0.2, 0.133, and 0.067 respectively starting from the current time interval.

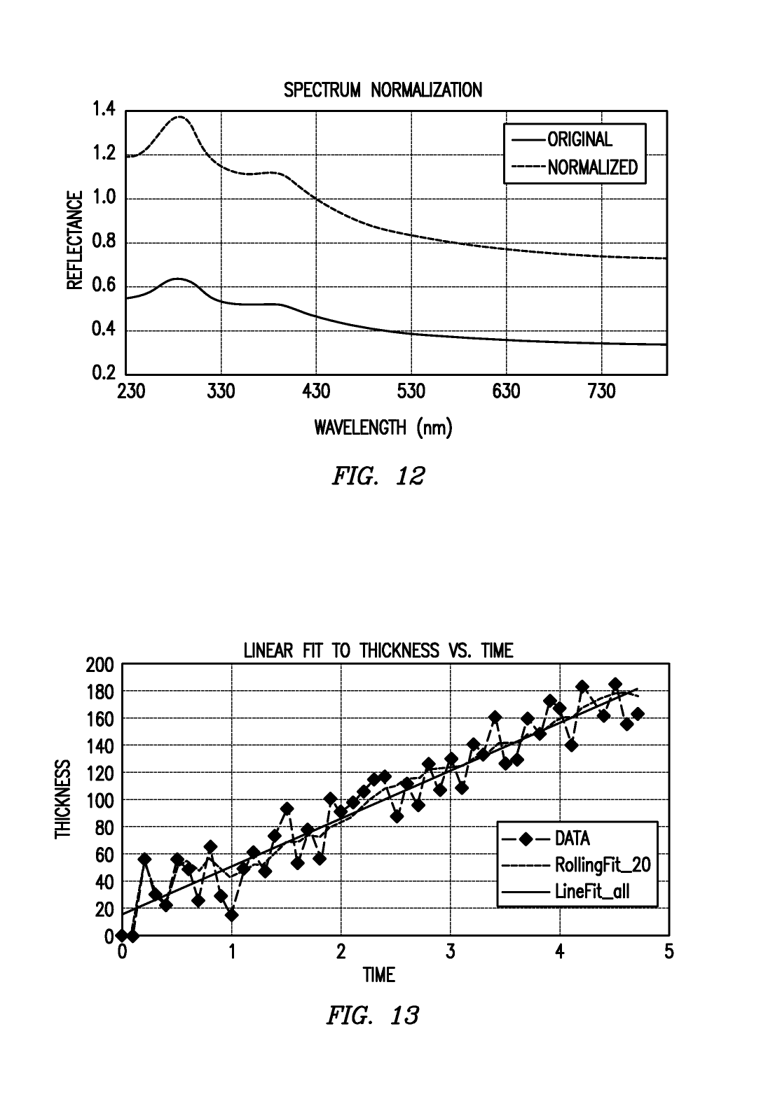

In another embodiment, each reflectance spectrum may be normalized. A reflectance spectrum may be normalized by the average value of the reflectance spectrum over a predefined range of wavelengths. The range of wavelengths may be selected according to properties of the reflectance spectrum. In one embodiment, the range of wavelengths may be as small as zero and the reflectance spectrum is normalized by a value at a single wavelength. Alternatively, the range of wavelengths may be as large as the entire wavelength range of the reflectance spectrum and the reflectance spectrum is normalized by the average value of the entire spectrum. FIG. 12 illustrates normalization of a reflectance spectrum according to one embodiment of the present disclosure.

One or more the noise reduction process may be used to process the reflectance spectrum prior to applying the reflectance spectrum to compute complex reflectivity of the substrate, and thickness of each layer in a film stack as disclosed above.

Alternatively, noise may be reduced by processing thickness results. In one embodiment, a line fit of the thickness results verse time for each layer may be applied to obtain a straight line. The straight line from the fit line provides a better estimate of the thickness compared to the original data of thickness results. The line fit may be performed using linear least square fit. The linear least square fit is suitable for the short duration of each layer deposition when the deposition rate can be expected to be a constant. The line fit may be applied to all the data points within each layer deposition. Alternatively, a rolling linear fit over a predefined number of data points may be applied. FIG. 13 includes linear fit of thickness results by a line fit of all data points and by rolling fit over 20 data points.

### Determining Time Zero

As discussed in box 330 of the method 300, time zero, the point of time when deposition starts, can be determined without relying process control software. Time zero provides the value of elapsed time t used in the dynamic time-series fit of that first layer data to obtain the substrate reflectivity and the deposition rate of the film (DR). Thickness at any given time t is calculated by multiplying the time elapsed t and the deposition rate DR. Thus, any error in initial time zero may negatively affect later computation results. Embodiments of the present disclosure provide methods for determining time zero.

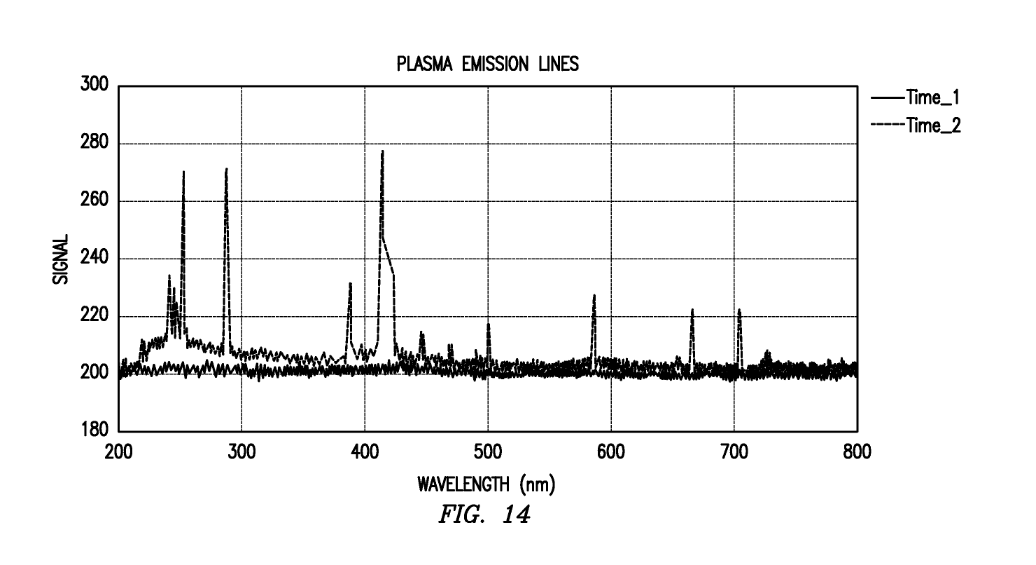

One embodiment time zero may be determined by detecting the first appearance of markers of plasma emissions. This embodiment takes advantage of the plasma emission background included in the reflectance spectrum as discussed earlier. Because the plasma emission is an integral part of the deposition process, the first appearance of markers indicating plasma emission in the spectrum detected by the metrology assembly indicates the beginning of the deposition process. The plasma emission marker generally contains narrow-band lines at specific wavelengths in the spectrum that depend on the species in the plasma. For example, plasma of oxygen, nitrogen, and silicon each has unique emission line signatures. FIG. 14 shows an example of plasma emission line signatures. Signal in Time_1 represents a detected spectrum without plasma emission in the background. Signal in Time_2 represents a detected spectrum with plasma emissions in the background. Spikes in the signal at Time_2 are plasma emission line signatures. By detecting the first appearance of the plasma emission line signatures, time zero can be determined.

In another embodiment, time zero can be determined by monitoring the change in reflectance, phase shift, at a given wavelength, or at a few wavelengths in first plurality of reflectance measurement points in the time series data. Derivative of phase shift as a function of time can then be fitted by a straight line, and extrapolated back to where phase-shift derivative equals zero to determine the exact time-zero.

In another embodiment, time zero may be determined by adding time zero as a variable to the dynamic time series data fitting to determine time zero during dynamic fitting. For example, a time zero variable t₀ may be added to the stack-film model of equations 1-7. Time is expressed as

t=t₀+n*dt

where t₀ is the unknown time-zero, n is the number of time intervals that are already counted until the present time, and dt is the time step between each data measurement. And equation 4 is replaced by

$${β}_{j} ( λ , t ) = \frac{2 π ( {n}_{j} - {ik}_{j} ) {D}_{R , j} ( t - {t}_{0} )}{λ} \qquad Equation {4}^{′}$$

While the foregoing is directed to embodiments of the present disclosure, other and further embodiments of the disclosure may be devised without departing from the basic scope thereof, and the scope thereof is determined by the claims that follow.

1. A method for measuring properties of a thin film, comprising:
positioning a substrate having an unknown surface in a processing chamber;
repeatedly measuring a reflectance spectrum of the substrate at a time interval to obtain a time series data;
flowing one or more processing gases to deposit the thin film over the substrate while maintaining repeated measurements;
determining one or more of properties the unknown surface of the substrate from a plurality of reflectance spectrum measurements in the time series data; and
determining thickness of the thin film according to the one or more properties of the unknown surface and reflectance spectrum measurement of the thin film.

2. The method of claim 1, further comprising igniting a plasma of the one or more processing gases, wherein measuring a reflectance spectrum comprises:
turning on a flash light source directed to the substrate and making a first measurement; and
turning off the flash light source and making a second measurement.

3. The method of claim 2, further comprising determining a time zero indicating the beginning of deposition of the thin film.

4. The method of claim 1, wherein determining one or more properties of the unknown surface comprises dynamic fitting the time series data to a film stack model.

5. The method of claim 4, wherein determining thickness of the thin film comprises static fitting one reflectance spectrum measurement to the film stack model.

6. A method for forming a film stack, comprising:
positioning a substrate in a plasma processing chamber;
repeatedly measuring a reflectance spectrum of the substrate at a time interval to obtain a time series data;
igniting plasma of processing gases to alternately deposit a first film and a second film in over the substrate while maintaining repeated measurement of reflectance spectrum;
determining a complex reflectivity of the substrate from a plurality of reflectance spectrum measurements in the time series data; and
determining thickness of each first film or second film according to the complex reflectivity of the substrate and a reflectance spectrum measurement of each first film or second film.

7. The method of claim 6, wherein measuring a reflectance spectrum comprises:
directing a light from a flash light source towards the substrate; and
measuring a first reflectance of the light from the substrate.

8. The method of claim 7, wherein measuring a reflectance spectrum further comprises:
measuring a second reflectance of the light from the substrate with the flash light source turned off; and
removing background noise by subtracting the second reflectance from the first reflectance.

9. The method of claim 6, further comprising determining a time zero indicating the beginning of deposition.

10. The method of claim 9, wherein determining time zero comprises detecting plasma emission line signatures from the first plurality of measurement of the time series data.

11. The method of claim 9, wherein determining time zero comprises monitoring phase shift from the first plurality of measurement of the time series data.

12. The method of claim 6, wherein determining complex reflectivity of the substrate comprises dynamic fitting the time series data to a film stack model.

13. The method of claim 12, wherein determining thickness of each first film or second film comprises static fitting a corresponding reflectance spectrum measurement to the film stack model.

14. The method of claim 13, wherein determining thickness of each first film or second film is performed in real time.

15. The method of claim 14, further comprising adjusting one or more processing parameters of the plasma processing chamber according to the determined thickness.

16. An apparatus for depositing one or more films, comprising:
a chamber body defining a processing volume;
a substrate support disposed in the processing volume; and
a metrology assembly disposed over the substrate support, wherein the metrology assembly comprises:
a flash light source;
a spectrometer;
a plurality of optical fiber channels connected between the flash light source and the spectrometer, wherein each optical fiber is positioned to direct a light from the flash light source towards a measurement point on the substrate support, receive reflectance from the measurement point, and direct the received reflectance to the spectrometer.

17. The apparatus of claim 16, wherein the metrology assembly further comprises a reference optical fiber channel connected between the flash light source and the spectrometer.

18. The apparatus of claim 17, further comprising a controller coupled to the metrology assembly, wherein the controller receives measurement data from the spectrometer.

19. The apparatus of claim 18, wherein the controller comprises a software, when operating, performs the following:
instructing the metrology assembly to repeatedly measuring a reflectance spectrum of a substrate in positioned on the substrate support at a time interval to obtain a time series data;
determining a complex reflectivity of the substrate from a plurality of reflectance spectrum measurements in the time series data; and
determining thickness of a film deposited on the substrate according to the complex reflectivity of the substrate and a reflectance spectrum measurement of the film.

20. The apparatus of claim 19, wherein determining complex reflectivity of the substrate comprises dynamic fitting the time series data to a film stack model.
